(19) United States
(12) Patent Application Publication
(10) Pub. No.: US 2026/0076254 A1
(43) Pub. Date: Mar. 12, 2026

(54) ULTRA LOW PROFILE RDL PACKAGE-ON-PACKAGE

(71) Applicant: QUALCOMM Incorporated, San Diego, CA (US)

(72) Inventors: Akshay BILAGI, San Diego, CA (US); Lohith Kumar VEMULA, George Town, TX (US); Sang-Jae LEE, San Diego, CA (US)

(21) Appl. No.: 18/827,477

(22) Filed: Sep. 6, 2024

(51) Int. Cl. H01L 25/065; H01L 23/00; H01L 23/31; H01L 23/498; H01L 25/00; H10B 80/00

(52) U.S. Cl. CPC H10W 90/00; H10W 74/111; H10B 80/00; H10W 70/093; H10W 70/6528; H10W 72/01; H10W 90/22; H10W 90/701

(57) ABSTRACT

Disclosed are semiconductor packages. A semiconductor package may include a first die encapsulated by a mold, and a second die directly on the mold. One or more conductive posts may be formed in the mold. A frontside redistribution layer (RDL) may be provided on a lower surface of the mold. Electrical signals between the first and second dies may be carried through the posts and the frontside RDL. There is no need for backside RDL and backside ball grid array. This can significantly reduce the height of the semiconductor package.

### BACKGROUND OF THE DISCLOSURE

### 1. Field of the Disclosure

This disclosure relates generally to die packages or modules, and more specifically, but not exclusively, to ultra low profile redistribution layer (RDL) package-on-package (PoP) and fabrication techniques thereof.

### 2. Description of the Related Art

Integrated circuit (IC) technology has achieved great strides in advancing computing power through miniaturization of active components. In current 5G and WiFi6 radio frequency (RF) frontend packages/modules, RFIC chips such as switches (SW), low noise amplifiers (LNA), power amplifiers (PA), digital amplifiers (DA), filters, etc. are placed side-by-side in a package, e.g., for an RF frontend module.

In semiconductor PoP packages, a die package and a memory package may be stacked together and connected. Such PoP packages require redistribution layers (RDL) on both sides of the die. This can increase the height of the PoP package. Such high profile packages can make it difficult to reduce sizes of devices where thinness is desired. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a first die comprising one or more first die bumps on a lower surface of the first die. The semiconductor package may also comprise a mold encapsulating side surfaces and an upper surface of the first die. The semiconductor package may further comprise a second die directly on an upper surface of the mold. The second die may comprise one or more second die bumps on a lower surface of the second die. The semiconductor package may yet comprise one or more posts in the mold. The one or more posts may be conductive and extend from the upper surface of the mold to a lower surface of the mold. At least one post may be electrically coupled with the second die through a corresponding at least one second die bump.

A method of fabricating a semiconductor package is disclosed. The method may comprise providing a first die comprising one or more first die bumps on a lower surface of the first die. The method may also comprise forming a mold encapsulating side surfaces and an upper surface of the first die. The method may further comprise providing a second die directly on an upper surface of the mold. The second die may comprise one or more second die bumps on a lower surface of the second die. The method may yet comprise forming one or more posts in the mold. The one or more posts may be conductive and extend from the upper surface of the mold to a lower surface of the mold. At least one post may be electrically coupled with the second die through a corresponding at least one second die bump.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross-sectional view of a conventional semiconductor package.

FIG. 2 illustrates a cross-sectional view of a semiconductor package in accordance with one or more aspects of the disclosure.

FIG. 3A-3C illustrate examples of stages of fabricating a semiconductor package in accordance with one or more aspects of the disclosure.

FIG. 4-6 illustrate flow charts of example methods of manufacturing a semiconductor package in accordance with at one or more aspects of the disclosure.

FIG. 7 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, the semiconductor package may comprise a first die comprising one or more first die bumps on a lower surface of the first die. The semiconductor package may also comprise a mold encapsulating side surfaces and an upper surface of the first die. The semiconductor package may further comprise a second die directly on an upper surface of the mold. The second die may comprise one or more second die bumps on a lower surface of the second die. The semiconductor package may yet comprise one or more posts in the mold. The one or more posts may be conductive and extend from the upper surface of the mold to a lower surface of the mold. At least one post may be electrically coupled with the second die through a corresponding at least one second die bump. In this way, the height of the semiconductor package can be reduced significantly.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to”perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

As indicated above, a die package and a memory package may be stacked together. Such PoP packages requires redistribution layers (RDL) on both sides of the die. This can increase the height of the PoP package. Such high profile packages can make it difficult to reduce sizes of devices where thinness is desired.

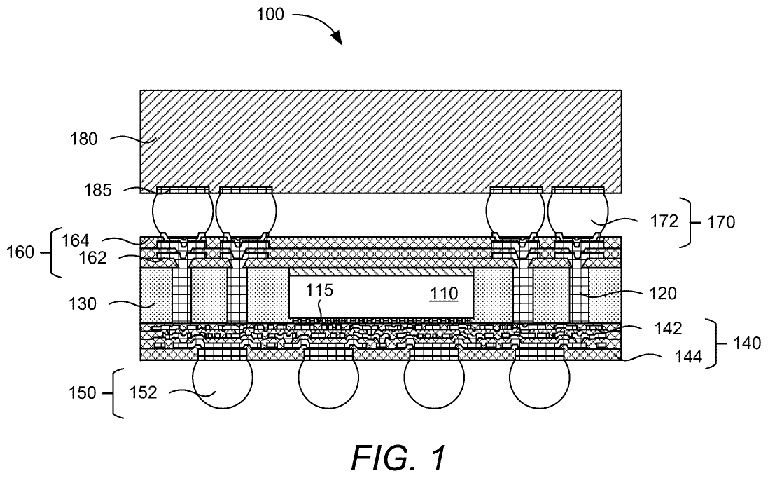

FIG. 1 illustrates a cross-sectional view of a conventional semiconductor package. The conventional semiconductor package 100 includes a die 110 and a mold 130 encapsulating the die 110. The die 110 includes die bumps 115 on a lower surface thereof. The die bumps 115 are provided for electrical connections (power, ground, signal) with and for the die 110. A plurality of copper (Cu) posts 120 are formed within the mold 130 and through upper and lower surfaces of the mold 130.

A frontside redistribution layer (RDL) 140 is formed below the die 110 and the mold 130. The frontside RDL 140 comprises multiple frontside metal layers 142 and multiple frontside passivation layers 144. Frontside ball grid array (BGA) 150 is formed below the frontside RDL 140. The frontside BGA 150 comprises a plurality of frontside BGA balls 152. External devices and/or packages (not shown) may be electrically coupled through the frontside BGA 150, i.e., through the frontside BGA balls 152.

A backside RDL 160 is formed above the die 110 and on the mold 130. The backside RDL 160 comprises multiple backside metal layers 162 and multiple backside passivation layers 164. Backside ball grid array (BGA) 170 is formed above the backside RDL 160. The backside BGA 170 comprises a plurality of backside BGA balls 172. A DRAM package 180 is provided on the backside BGA 170. DRAM bumps 185 provided on a bottom of the DRAM package are electrically coupled with the memory dies (not shown) within the DRAM package.

Signals between the memories within the DRAM package 180 and the die 110 may be carried through the DRAM bumps 185, the backside BGA 170, the backside RDL 160, the Cu posts 120, and the frontside RDL 140. Signals between the memories within the DRAM package 180 and external devices/packages may be carried through the DRAM bumps 185, the backside BGA 170, the backside RDL 160, the Cu posts 120, the frontside RDL 140, and the frontside BGA 150. Further, signals between the die 110 and external devices may be carried through the frontside BGA 150.

Regarding package-on-packages, the conventional semiconductor package 100 is an example of a “raised solution” in which the backside RDL 160 is present. The backside RDL 160 is used to connect to the DRAM package 180, i.e., to couple the DRAM to the die 110. One purpose of the backside RDL 160 is to match the pitches of the backside BGA balls 172, which can be around 350 μm. Note that the pitches the bumps of the memory die itself within the DRAM package 180 can be much less. Thus, connections within the DRAM package transition from the memory die or dies of the DRAM package 180 to the DRAM bumps 185, and hence to the backside BGA balls 172.

On the other hand, the pitches between adjacent Cu posts 120 can be as small as 150 μm. Thus, the backside RDL 160 enables fan-in transitions from the pitches of the backside BGA balls 172 to the pitches of the Cu posts 120. To accommodate the significant amount of fan-in, multiple backside metal and passivation layers 162, 164 are required. In addition, the backside BGA balls 172 are much larger than the Cu posts 120. Hence, the pads of the backside RDL 160 must also be correspondingly large. Note that the backside BGA 170 and the backside RDL 160 comprise a significant portion of the height of the conventional semiconductor package 100.

To address these and other issues (e.g., increased height) of the conventional semiconductor package, utilize the dies themselves without the package aspects such as substrates and transition connections. For example, instead of using the DRAM package, only the memory dies may be used. This can reduce the height in at least two ways. First, the backside BGA balls (˜135 μm tall) would be unnecessary, and hence can be removed. Second, the backside RDL (˜30 μm tall) would also be unnecessary, and hence can be removed as well.

There can be additional benefits or technical advantages with the proposed semiconductor package. The bumps/pads of the memory dies may be connected directly to the posts. This means that the electrical distance between the memory die and other components of the semiconductor package, such as the die within the mold, frontside BGA, etc. This can result in cleaner and/or faster signaling. Also, since there is no need to relax the pitches required for the backside BGA balls, the tight pitches of the memory die bumps/pads may be kept. This can result in further reductions in size.

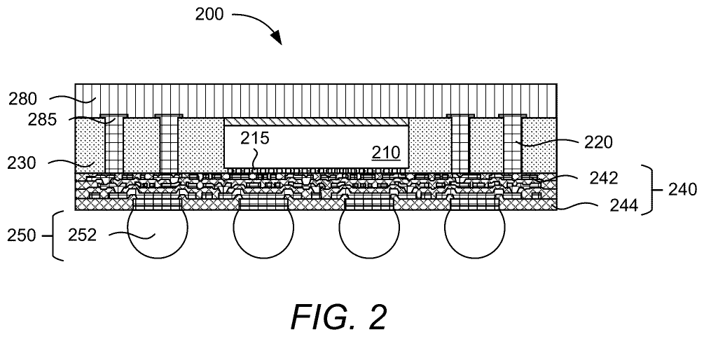

FIG. 2 illustrates a cross-sectional view of a semiconductor package 200 in accordance with one or more aspects of the disclosure. The semiconductor package 200 may include a first die 210, a second die 280, and a mold 230. The first die 210 may comprise one or more first die bumps 215 on a lower surface of the first die 210. The mold 230 may encapsulate the first die 210. For example, the mold 230 may encapsulate one or more surfaces—e.g., side surfaces, upper surface, etc.—of the first die 210. The second die 280 may comprise one or more second die bumps 285 on a lower surface of the second die 280. The second die 280 may be on an upper surface of the mold 230. In an aspect, the second die 280 may be directly on, e.g., in direct contact with, the upper surface of the mold 230.

The first die 210 may be a system-on-chip (SoC) die. Alternatively or in addition thereto, the second die 280 may be a memory die. However, it should be noted that there are no particular restrictions on the types of dies. That is, first die 210 may be a general processor die, and/or the second die 280 may be a graphics processor die, etc. It is also significant that the second die 280 is NOT a semiconductor die package in and of itself. That is, the second die 280 need not include other aspects of a package such as substrate, connection transitions (e.g., to relax pitch distances), etc.

The semiconductor package 200 may also include one or more posts 220 in the mold 230. The one or more posts 220 may be conductive and extend from the upper surface of the mold 230 to a lower surface of the mold 230. At least one post 220 may be electrically coupled with the second die 280 through a corresponding at least one second die bump 285. More generally, some or all of the one or more posts 220 may be configured to couple with the second die 280 through the one or more second die bumps 285. For example, some or all of the one or more posts 220 may be in direct contact with some or all of the second die bumps 285. The one or more posts 220 may be formed from conductive materials such as copper (Cu).

In an aspect, the second die bumps 285 may have tight pitches. For example, pitches between adjacent second die bumps 285 may be 150μm or even smaller. This implies that the pitches of the posts 220, which can match the pitches of the second die bumps 285, may also be tight.

As seen, unlike the conventional semiconductor package 100 of FIG. 1, the semiconductor package 200 of FIG. 2 need not include any RDL between the mold 230 and the second die 280 (e.g., need not include any backside RDL). Alternatively or in addition thereto, the semiconductor package 200 need not include any BGA between the mold 230 and the second die 280 (e.g., need not include any backside BGA). As a result, the height of the semiconductor package 200 can be significantly reduced as compared to the conventional semiconductor package 100.

The semiconductor package 200 may further include a frontside (BGA) 250 on a lower surface of the mold 130 and on a lower surface of the first die 210. The frontside RDL 240 may comprise one or more frontside metal layers 242 and one or more frontside passivation layers 244. The frontside RDL 240 may be electrically coupled with the one or more posts 220. The frontside RDL 240 may also be electrically coupled with the first die 210 through the one or more first die bumps 215. In this way, signals between the first and second dies 210, 280 may be carried through the posts 220 and the frontside RDL 240.

To enable communications with external devices, the semiconductor package 200 may further include a frontside BGA 250 on a lower surface of the frontside RDL 240. The frontside BGA 250 may comprise one or more frontside BGA balls 252. The frontside BGA 250 (e.g., through the frontside BGA balls 252) may be electrically coupled with the frontside RDL 240. In this way, the first die 210 may communicate with devices external to the semiconductor package 200 through the frontside RDL 240 and the frontside BGA 250. The second die 280 may communicate with devices external to the semiconductor package 200 through the posts 220, the frontside RDL 240 and the frontside BGA 250.

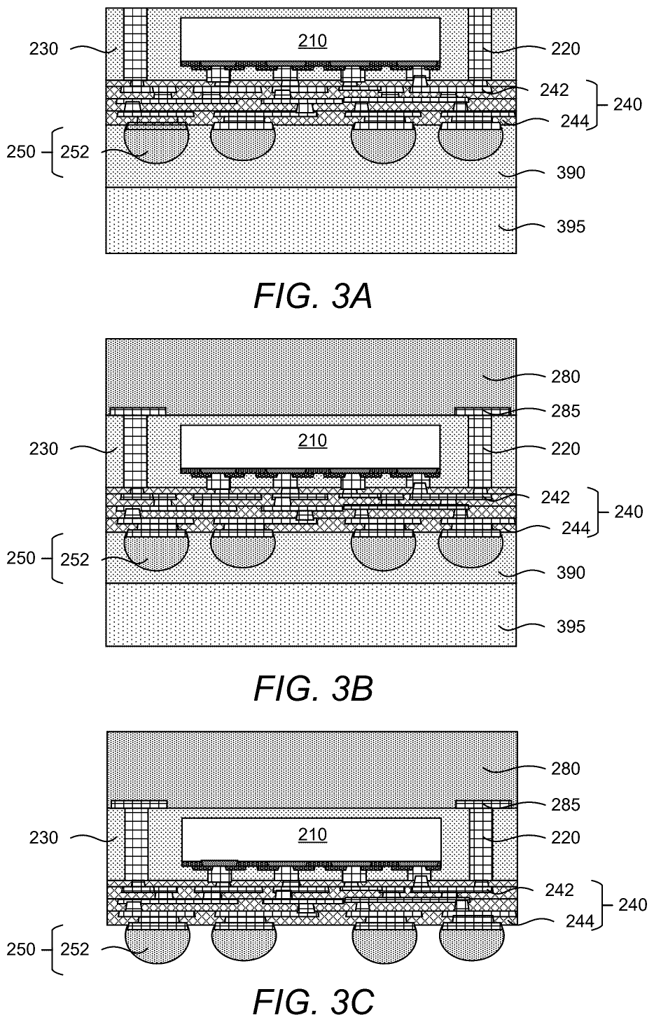

FIG. 3A-3C illustrate examples of stages of fabricating a semiconductor package in accordance with one or more aspects of the disclosure. FIG. 3A illustrates a stage in which the first die 210, the mold 230, the posts 220, the frontside RDL 240 and the frontside BGA 250 have been formed. In an aspect, the stage of FIG. 3A may represent a wafer level stage in which multiple semiconductor packages 200 are formed, and FIG. 3A illustrates a single semiconductor package of a wafer that includes multiple semiconductor packages. An adhesive 390 (e.g., glue) and a carrier 395 (e.g., a glass carrier) may be provided to adhere to the wafer.

FIG. 3B illustrates a stage in which the second dies 280 may be attached to the mold 230. The second dies 280 may be attached such that the second die bumps 285 are aligned with the posts 220.

FIG. 3C illustrates a stage in which the adhesive 290 and the carrier 395 are removed from the wafer, and the wafer is diced/singulated to individual semiconductor packages 200.

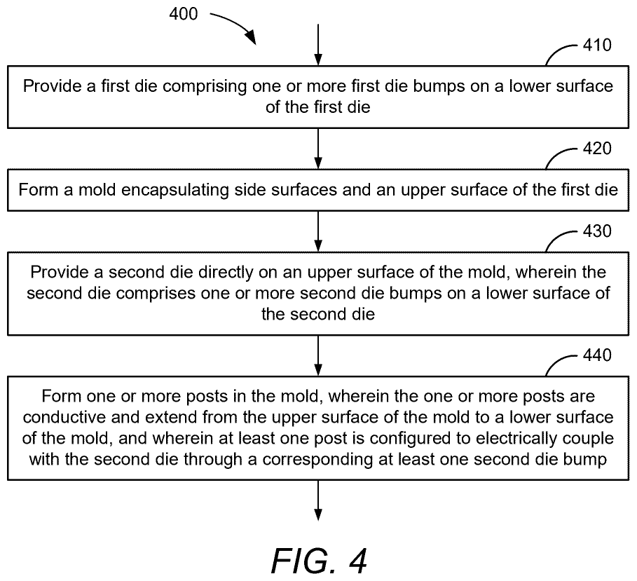

FIG. 4 illustrates a flow chart of an example method 400 of fabricating a semiconductor package, such as the semiconductor package 200, in accordance with at one or more aspects of the disclosure.

In block 410, a first die 210 may be provided. The first die 210 may comprise one or more first die bumps 215 on a lower surface of the first die 210.

In block 420, the mold 230 may be formed. The mold 230 may encapsulate side surfaces and an upper surface of the first die 210.

In block 430, the second die 280 may be provided directly on an upper surface of the mold 230. The second die 280 may comprise one or more second die bumps 285 on a lower surface of the second die 280.

In block 440, one or more posts 220 may be formed in the mold 230. The one or more posts 220 may be conductive and extend from the upper surface of the mold 230 to a lower surface of the mold 230. At least one post 220 may be electrically coupled with the second die 280 through a corresponding at least one second die bump 285.

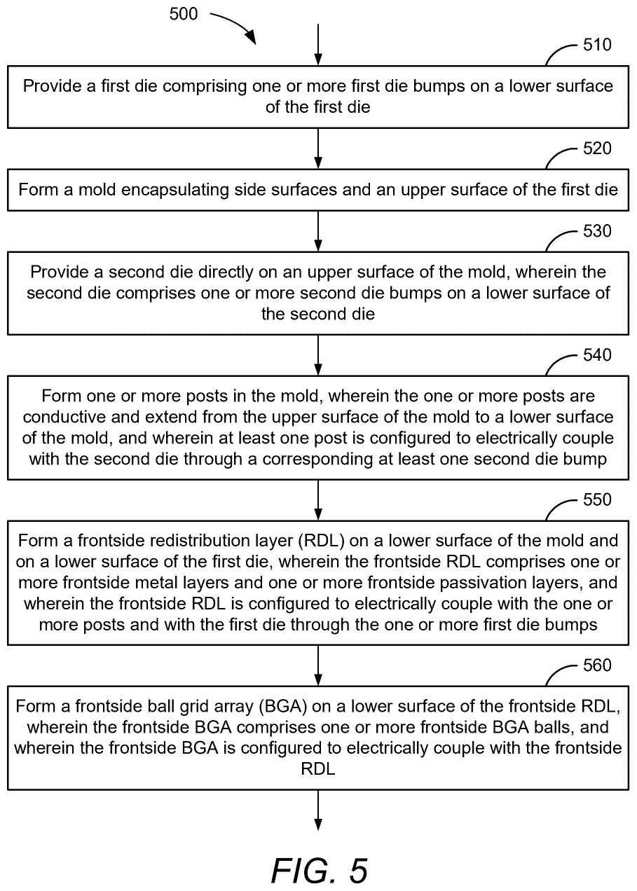

FIG. 5 illustrates a flow chart of an example method 500 of fabricating a semiconductor package, such as the semiconductor package 200 in accordance with at one or more aspects of the disclosure. FIG. 5 may be viewed as being more comprehensive than FIG. 4.

Block 510 may be similar to block 410. That is, in block 510, a first die 210 may be provided. The first die 210 may comprise one or more first die bumps 215 on a lower surface of the first die 210.

Block 520 may be similar to block 420. That is, in block 520, the mold 230 may be formed. The mold 230 may encapsulate side surfaces and an upper surface of the first die 210.

Block 530 may be similar to block 430. That is, in block 530, the second die 280 may be provided directly on an upper surface of the mold 230. The second die 280 may comprise one or more second die bumps 285 on a lower surface of the second die 280.

Block 540 may be similar to block 440. That is, in block 540, one or more posts 220 may be formed in the mold 230. The one or more posts 220 may be conductive and extend from the upper surface of the mold 230 to a lower surface of the mold 230. At least one post 220 may be electrically coupled with the second die 280 through a corresponding at least one second die bump 285.

In block 550, a frontside redistribution layer (RDL) 240 may be formed on a lower surface of the mold 230 and on a lower surface of the first die 210. The frontside RDL 240 may comprise one or more frontside metal layers 242 and one or more frontside passivation layers 244. The frontside RDL 240 may be electrically coupled with the one or more posts 220 and with the first die 210 through the one or more first die bumps 215.

In block 560, a frontside BGA 250 may be formed on a lower surface of the frontside RDL 240. The frontside BGA 250 may comprise one or more frontside BGA balls 252. The frontside BGA 250 may be electrically coupled with the frontside RDL 240.

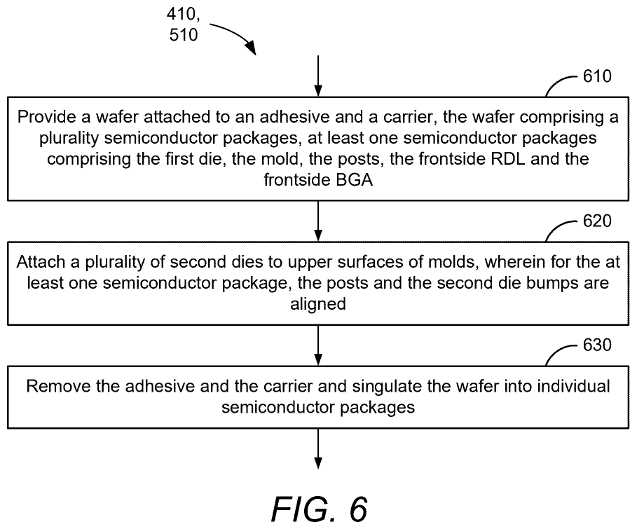

FIG. 6 illustrates a flow chart of an example process to perform block 410 of FIG. 4 (and hence block 510 of FIG. 5).

In block 610, a wafer attached to an adhesive 390 and a carrier 395 may be provided. The wafer may comprise a plurality semiconductor packages 200. At least one semiconductor package 200 may comprise the first die 210, the mold 230, the posts 220, the frontside RDL 240 and the frontside BGA 250. Block 610 may be analogous to FIG. 3A.

In block 620, a plurality of second dies 280 may be attached to upper surfaces of the mold 230. For the at least one semiconductor package 200, the posts 220 and the second die bumps 285 may be aligned. Block 620 may be analogous to FIG. 3B.

In block 630, the adhesive 390 and the carrier 395 may be removed. Also, the wafer may be singulated into individual semiconductor packages 200. Block 630 may be analogous to FIG. 3C.

The following should be noted regarding the flow indicated in FIG. 4 - 6. Unless otherwise indicated, the flow of blocks do not necessarily limit the ordering in which the blocks may be performed. In other words, the blocks may be performed in any order that is logical.

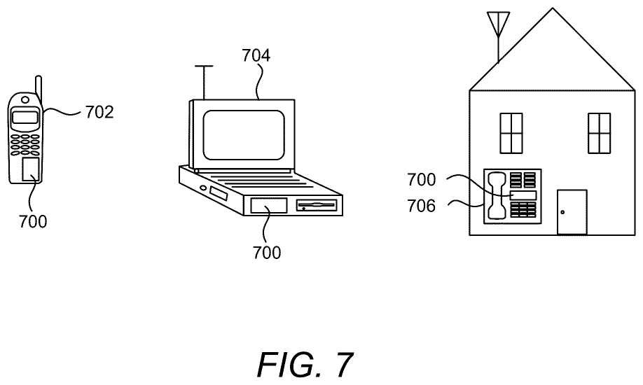

FIG. 7 illustrates various electronic devices 700 that may be integrated with any of the aforementioned semiconductor package in accordance with various aspects of the disclosure. For example, a mobile phone device 702, a laptop computer device 704, and a fixed location terminal device 706 may each be considered generally user equipment (UE) and may include one or more semiconductor packages (e.g., semiconductor package 200) as described herein. The devices 702, 704, 706 illustrated in FIG. 7 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A semiconductor package, comprising: a first die comprising one or more first die bumps on a lower surface of the first die; a mold encapsulating side surfaces and an upper surface of the first die; a second die directly on an upper surface of the mold, wherein the second die comprises one or more second die bumps on a lower surface of the second die; and one or more posts in the mold, wherein the one or more posts are conductive and extend from the upper surface of the mold to a lower surface of the mold, and wherein at least one post is electrically coupled with the second die through a corresponding at least one second die bump.
Clause 2: The semiconductor package of clause 1, wherein the at least one post is in direct contact with the at least one second die bump.
Clause 3: The semiconductor package of clause any of clauses 1-2, further comprising: a frontside redistribution layer (RDL) on a lower surface of the mold and on a lower surface of the first die, wherein the frontside RDL comprises one or more frontside metal layers and one or more frontside passivation layers, and wherein the frontside RDL is electrically coupled with the one or more posts and with the first die through the one or more first die bumps.
Clause 4: The semiconductor package of clause 3, further comprising: a frontside ball grid array (BGA) on a lower surface of the frontside RDL, wherein the frontside BGA comprises one or more frontside BGA balls, and wherein the frontside BGA is electrically coupled with the frontside RDL.
Clause 5: The semiconductor package of clause any of clauses 1-4, wherein there is no redistribution layer (RDL) between the mold and the second die.
Clause 6: The semiconductor package of clause any of clauses 1-5, wherein there is no ball grid array (BGA) between the mold and the second die.
Clause 7: The semiconductor package of clause any of clauses 1-6, wherein a pitch between adjacent second die bumps is less than or equal to 150 μm.
Clause 8: The semiconductor package of clause any of clauses 1-7, wherein the first die is a system-on-chip (SoC) die, or the second die is a memory die, or both.
Clause 9: The semiconductor package of clause any of clauses 1-8, wherein the second die is not a die package.
Clause 10: The semiconductor package of clause any of clauses 1-9, wherein the one or more posts are formed from copper (Cu).
Clause 11: The semiconductor package of clause any of clauses 1-10, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 12: A method of fabricating a semiconductor package, the method comprising: providing a first die comprising one or more first die bumps on a lower surface of the first die; forming a mold encapsulating side surfaces and an upper surface of the first die; providing a second die directly on an upper surface of the mold, wherein the second die comprises one or more second die bumps on a lower surface of the second die; and forming one or more posts in the mold, wherein the one or more posts are conductive and extend from the upper surface of the mold to a lower surface of the mold, and wherein at least one post is electrically coupled with the second die through a corresponding at least one second die bump.
Clause 13: The method of claim 12, wherein the at least one post is in direct contact with the at least one second die bump.
Clause 14: The method of clause any of clauses 12-13, further comprising: forming a frontside redistribution layer (RDL) on a lower surface of the mold and on a lower surface of the first die, wherein the frontside RDL comprises one or more frontside metal layers and one or more frontside passivation layers, and wherein the frontside RDL is electrically coupled with the one or more posts and with the first die through the one or more first die bumps.
Clause 15: The method of claim 14, further comprising: forming a frontside ball grid array (BGA) on a lower surface of the frontside RDL, wherein the frontside BGA comprises one or more frontside BGA balls (252), and wherein the frontside BGA is electrically coupled with the frontside RDL.
Clause 16: The method of clause any of clauses 12-15, wherein there is no redistribution layer (RDL) between the mold and the second die.
Clause 17: The method of clause any of clauses 12-16, wherein there is no ball grid array (BGA) between the mold and the second die.
Clause 18: The method of clause any of clauses 12-17, wherein a pitch between adjacent second die bumps is less than or equal to 150 μm.
Clause 19: The method of clause any of clauses 12-18, the first die is a system-on-chip (SoC) die, or the second die is a memory die, or both.
Clause 20: The method of clause any of clauses 12-19, wherein the second die is not a die package.
Clause 21: The method of clause any of clauses 12-20, wherein providing the second die comprises: providing a wafer attached to an adhesive and a carrier, the wafer comprising a plurality semiconductor packages, at least one semiconductor package comprising the first die, the mold, the posts, a frontside RDL and a frontside BGA; attaching a plurality of second dies to upper surfaces of the mold, wherein for the at least one semiconductor package, the posts and the second die bumps are aligned; and removing the adhesive and the carrier and singulating the wafer into individual semiconductor packages.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a first die comprising one or more first die bumps on a lower surface of the first die;
a mold encapsulating side surfaces and an upper surface of the first die;
a second die directly on an upper surface of the mold, wherein the second die comprises one or more second die bumps on a lower surface of the second die; and
one or more posts in the mold, wherein the one or more posts are conductive and extend from the upper surface of the mold to a lower surface of the mold, and wherein at least one post is electrically coupled with the second die through a corresponding at least one second die bump.

2. The semiconductor package of claim 1, wherein the at least one post is in direct contact with the at least one second die bump.

3. The semiconductor package of claim 1, further comprising:
a frontside redistribution layer (RDL) on a lower surface of the mold and on a lower surface of the first die,
wherein the frontside RDL comprises one or more frontside metal layers and one or more frontside passivation layers, and
wherein the frontside RDL is electrically coupled with the one or more posts and with the first die through the one or more first die bumps.

4. The semiconductor package of claim 3, further comprising:
a frontside ball grid array (BGA) on a lower surface of the frontside RDL,
wherein the frontside BGA comprises one or more frontside BGA balls (252), and
wherein the frontside BGA is electrically coupled with the frontside RDL.

5. The semiconductor package of claim 1, wherein there is no redistribution layer (RDL) between the mold and the second die.

6. The semiconductor package of claim 1, wherein there is no ball grid array (BGA) between the mold and the second die.

7. The semiconductor package of claim 1, wherein a pitch between adjacent second die bumps is less than or equal to 150 μm.

8. The semiconductor package of claim 1, wherein
the first die is a system-on-chip (SoC) die, or
the second die is a memory die, or
both.

9. The semiconductor package of claim 1, wherein the second die is not a die package.

10. The semiconductor package of claim 1, wherein the one or more posts are formed from copper (Cu).

11. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

12. A method of fabricating a semiconductor package, the method comprising:
providing a first die comprising one or more first die bumps on a lower surface of the first die;
forming a mold encapsulating side surfaces and an upper surface of the first die;
providing a second die directly on an upper surface of the mold, wherein the second die comprises one or more second die bumps on a lower surface of the second die; and
forming one or more posts in the mold, wherein the one or more posts are conductive and extend from the upper surface of the mold to a lower surface of the mold, and wherein at least one post is electrically coupled with the second die through a corresponding at least one second die bump.

13. The method of claim 12, wherein the at least one post is in direct contact with the at least one second die bump.

14. The method of claim 12, further comprising:
forming a frontside redistribution layer (RDL) on a lower surface of the mold and on a lower surface of the first die,
wherein the frontside RDL comprises one or more frontside metal layers and one or more frontside passivation layers, and
wherein the frontside RDL is electrically coupled with the one or more posts and with the first die through the one or more first die bumps.

15. The method of claim 14, further comprising:
forming a frontside ball grid array (BGA) on a lower surface of the frontside RDL,
wherein the frontside BGA comprises one or more frontside BGA balls (252), and
wherein the frontside BGA is electrically coupled with the frontside RDL.

16. The method of claim 12,
wherein there is no redistribution layer (RDL) between the mold and the second die, or
wherein there is no ball grid array (BGA) between the mold and the second die, or
both.

17. The method of claim 12, wherein a pitch between adjacent second die bumps is less than or equal to 150 μm.

18. The method of claim 12, wherein
the first die is a system-on-chip (SoC) die, or
the second die is a memory die, or
both.

19. The method of claim 12, wherein the second die is not a die package.

20. The method of claim 12, wherein providing the second die comprises:
providing a wafer attached to an adhesive and a carrier, the wafer comprising a plurality semiconductor packages, at least one semiconductor package comprising the first die, the mold, the posts, a frontside RDL and a frontside BGA;
attaching a plurality of second dies to upper surfaces of the mold, wherein for the at least one semiconductor package, the posts and the second die bumps are aligned; and
removing the adhesive and the carrier and singulating the wafer into individual semiconductor packages.
